(19) United States
(12) Patent Application Publication
(10) Pub. No.: US 2014/0306280 A1
(43) Pub. Date: Oct. 16, 2014

(54) SEMICONDUCTOR DEVICES AND METHODS OF MANUFACTURING THE SAME

(71) Applicant: SAMSUNG ELECTRONICS CO., LTD., Suwon-Si (KR)

(72) Inventors: Je-Dong LEE, Hwaseong-si (KR); Young-Il KIM, Osan-si (KR); Il-Woo KIM, Yongin-si (KR); Kwang-Jae LEE, Suwon-si (KR); In-Hwa JEON, Suwon-si (KR); Sung-Joon HWANG, Yongin-si (KR)

(73) Assignee: SAMSUNG ELECTRONICS CO., LTD., Suwon-Si (KR)

(21) Appl. No.: 14/231,919

(22) Filed: Apr. 1, 2014

(30) Foreign Application Priority Data
Apr. 11, 2013 (KR) 10-2013-0039712

(51) Int. Cl. H01L 29/423; H01L 21/28

(52) U.S. Cl. CPC H01L 29/42324; H01L 21/28273
USPC 257/321; 438/587

(57) ABSTRACT

In the method, a plurality of gate structures may be formed on a substrate and be spaced apart from each other in a first direction. An insulation layer pattern may be formed by performing a chemical vapor deposition process using SiH₄ gas as a source gas. The insulation layer pattern may partially define an air gap between the adjacent gate structures. A width of the air gap in the first direction may be about 65% to about 70% of a distance between the adjacent gate structures.

### CLAIM OF PRIORITY

This application claims priority under 35 USC §119 to Korean Patent Application No. 2013-0039712, filed on Apr. 11, 2013 in the Korean Intellectual Property Office (KIPO), the contents of which are herein incorporated by reference in their entirety.

### BACKGROUND

1. Field

Example embodiments relate to semiconductor devices and/or methods of manufacturing semiconductor devices. Particularly, example embodiments relate to semiconductor device having air gaps and/or methods of manufacturing the same.

2. Description of the Related Art

Recently, as semiconductor devices are highly integrated, a distance between gate structures or word lines also decreases. Therefore, a parasitic capacitance or a cell coupling between the gate structures or the word lines occurs, thus changing a threshold voltage of the gate structure.

Therefore, semiconductor devices that prevent or reduce the parasitic capacitance or the cell coupling are being studied.

### SUMMARY

Some example embodiments provide semiconductor devices having a reduced parasitic capacitance.

Some example embodiments provide methods of manufacturing a semiconductor device having a reduced parasitic capacitance.

According to an example embodiment, a method of manufacturing a semiconductor device may include forming a plurality of gate structures on a substrate, the plurality of gate structures spaced apart from each other in a first direction, and forming an insulation layer pattern by performing a chemical vapor deposition process using SiH4 gas as a source gas, the insulation layer pattern partially defining an air gap between the adjacent gate structures. A width of the air gap in the first direction may be about 65% to about 70% of a distance between the adjacent gate structures.

The insulation layer pattern may define a top portion and side portions of the air gap.

The forming an insulation layer pattern may form the insulation layer pattern using silicon oxide.

The performing a chemical vapor deposition process may include generating plasma in a process chamber.

The performing a chemical vapor deposition process may include using N₂O gas as an oxidation gas.

The forming a plurality of gate structures may include sequentially forming a tunnel insulation layer, a floating gate layer, a blocking layer, a control gate layer, and a gate mask layer on the substrate, and partially removing the floating gate layer, the blocking layer, the control gate layer, and the gate mask layer to form a floating gate, a blocking pattern, a control gate, and a gate mask, respectively.

Further, the method may include partially oxidizing the gate mask to form an oxidation pattern before performing the chemical vapor deposition process. The oxidation pattern may project in a direction parallel to a top surface of the substrate. The forming a gate mask layer may forms the gate mask layer using silicon nitride.

The method may further include forming a plurality of target patterns on respective ones of the gate structures, respectively, and performing a sputtering process using the target patterns as a sputtering target before the forming an insulation layer pattern such that a distance between the adjacent target patterns is reduced.

The method may further include forming a plurality of catalyst patterns on respective ones of the gate structures. The catalyst patterns may promote an oxidation of the source gas.

The tunnel insulation layer may define a bottom portion of the air gap.

The distance between the adjacent gate structures may be about 5 nm to about 20 nm.

According to an example embodiment, a semiconductor device may include a plurality of gate structures and an insulation layer pattern. The plurality of gate structures may be disposed on a substrate and spaced apart from each other in a first direction. The insulation layer pattern may be disposed between the adjacent gate structures. The insulation layer pattern may partially define an air gap extending in a second direction, the second direction substantially perpendicular to the first direction. A width of the air gap in the first direction may be about 65% to about 70% of a distance between the adjacent gate structures.

Each of the gate structures may include a tunnel insulation layer, a floating gate, a blocking pattern, a control gate and a gate mask sequentially stacked on the substrate.

The insulation layer pattern may define a top portion and side portions of the air gap surrounded by the insulation layer pattern, and the tunnel insulation layer may define a bottom surface of the air gap.

The insulation layer pattern may include silicon oxide.

According to an example embodiment, a method of forming a semiconductor device may include forming a plurality of gate structures on a substrate, the gate structures spaced apart from each other in a first direction, forming a plurality of intermediate structures on top portions of respective ones of the gate structures such that the intermediate structures at least partially cover sidewalls of respective ones of the gate structures, and forming an insulation layer on the intermediate structures, the insulation layer filling openings defined between adjacent intermediate structures and covering side portions of the gate structures such that a plurality of air gaps are arranged under the insulation layer, the air gaps extending in a second direction, the second direction perpendicular to the first direction.

The forming a plurality of gate structures may include sequentially forming a tunnel insulation layer, a floating gate layer, a blocking layer, a control gate layer, and a gate mask layer on the substrate, and partially removing the floating gate layer, the blocking layer, the control gate layer, and the gate mask layer to form the gate structures each including a floating gate, a blocking pattern, a control gate, and a gate mask.

The forming a plurality of intermediate structures may include partially oxidizing the gate mask.

The forming a plurality of gate structures may further include forming a plurality of target patterns on respective ones of the gate mask patterns, and the forming a plurality of intermediate structures may include performing a sputtering process around the target patterns.

The forming a plurality of gate structures may further include forming a plurality of catalyst patterns on respective ones of the gate mask patterns.

According to example embodiments, an insulation layer may be formed by a PECVD process using SiH₄ gas as a source gas and N₂O gas as an oxidation gas at a relative low pressure. The insulation layer formed by the PECVD process may have a relatively poor gap fill characteristic. Thus, an air gap having a relatively large width may be formed in the insulation layer. Accordingly, a coupling capacitance between the adjacent gate structures may decrease.

### BRIEF DESCRIPTION OF THE DRAWINGS

Example embodiments will be more clearly understood from the following detailed description taken in conjunction with the accompanying drawings. FIGS. 1 to 20 represent non-limiting, example embodiments as described herein.

FIG. 1 is a cross-sectional view illustrating a semiconductor device in accordance with an example embodiment;

FIGS. 2 to 8 are cross-sectional views illustrating a method of manufacturing a semiconductor device in accordance with an example embodiment;

FIGS. 9 to 12 are cross-sectional views illustrating a method of manufacturing a semiconductor device in accordance with an example embodiment;

FIGS. 13 to 16 are cross-sectional views illustrating a method of manufacturing a semiconductor device in accordance with an example embodiment;

FIGS. 17 to 19 are cross-sectional views illustrating a method of manufacturing a semiconductor device in accordance with an example embodiment; and

FIG. 20 is a block diagram illustrating a system including the semiconductor device according to an example embodiment.

### DETAILED DESCRIPTION

Various example embodiments will be described more fully hereinafter with reference to the accompanying drawings, in which some example embodiments are shown. The present inventive concepts may, however, be embodied in many different forms and should not be construed as limited to the example embodiments set forth herein. Rather, these example embodiments are provided so that this description will be thorough and complete, and will fully convey the scope of the present inventive concepts to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present inventive concepts.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present inventive concepts. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present inventive concepts.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, example embodiments will be explained in detail with reference to the accompanying drawings.

FIG. 1 is a cross-sectional view illustrating a semiconductor device in accordance with an example embodiment. In this example embodiment, the semiconductor device may be a floating type memory device.

Referring to FIG. 1, the semiconductor device may include a plurality of gate structures 115 on a substrate 100, and an insulation layer pattern 165 on the substrate 100 between the gate structures 115.

The gate structures 115 may be arranged in a first direction substantially parallel to a top surface of the substrate 100. Each of the gate structures 115 may extend in a second direction substantially perpendicular to the first direction. Further, an air gap 170 may be disposed in the insulation layer pattern 165 between the adjacent gate structures 115.

The substrate 100 may include a semiconductor substrate, e.g., a silicon substrate, a germanium substrate or a silicon-germanium substrate, and a silicon-on-insulator (SOI) substrate or a germanium-on-insulator (GOI) substrate. The substrate 100 may be divided into an active region and a field region depending on a plurality of isolation layer (not shown).

The gate structure 115 may include a tunnel insulation layer 110, a floating gate 122, a blocking pattern 132, a control gate 142, and a gate mask 152, which may be sequentially stacked on the substrate 100.

The tunnel insulation layer 110 may be disposed in the active region on the substrate 100. For example, the tunnel insulation layer 110 may include a low-k dielectric material, e.g., silicon oxide, silicon oxy nitride and doped silicon oxide.

The floating gate 122 may be disposed on the tunnel insulation layer 110. In example embodiments, the floating gate 122 may include highly doped polysilicon or metal having a relatively high work function, e.g., tungsten, titanium, cobalt, and nickel. Alternatively, a charge trapping pattern including, e.g., silicon nitride, silicon oxy nitride, hafnium silicon oxide, or aluminum oxide may be disposed on the tunnel insulation layer to trap or store a charge.

The blocking pattern 132 may be disposed on the floating gate 122. The blocking pattern 132 may include a material having a dielectric constant higher than that of the tunnel insulation layer 110. For example, the blocking pattern 132 may include a high-k dielectric material, e.g., hafnium oxide, titanium oxide, tantalum oxide, zirconium oxide, aluminum oxide, lanthanum oxide, and strontium titanium oxide. Alternatively, the blocking pattern 132 may include an ONO layer structure having, e.g., at least two oxide layers and a nitride layer therebetween.

The control gate 142 may be disposed on the blocking pattern 132. The control gate 142 may extend in the second direction, and may serve as a word line of the semiconductor device. For example, the control gate 142 may include doped polysilicon, metal, or metal nitride (e.g., titanium nitride and tantalum nitride).

The gate mask 152 may be disposed on the control gate 142. For example, the gate mask 152 may include silicon nitride or silicon oxide.

A gate spacer 185 may be disposed on sidewall of the gate structure 115. The gate spacer 185 may extend in the second direction. For example, the gate spacer 185 may include silicon nitride.

The insulation layer pattern 165 may be disposed on the substrate 100 and between the adjacent gate structures 115. Further, an air gap 170 may be provided in the insulation layer pattern 165 and may extend in the second direction.

The air gap 170 may be defined by the insulation layer pattern 165 and the tunnel insulation layer 110. For example, a top portion and side portions of the air gap 170 may be surrounded by the insulation layer pattern 165, and a bottom surface of the air gap 170 may be surrounded by the tunnel insulation layer 110.

According to this example embodiment, the air gap 170 may have a first width W1 in the first direction. When a first distance D1 is defined as a distance between the adjacent gate structures 115 in the first direction, the first width W1 of the air gap 170 in the first direction may be about 65% to about 70% of the first distance D1 between the adjacent gate structures 115. As a width of the air gap 170 increases, a coupling capacitance between the adjacent gate structures 115 decreases.

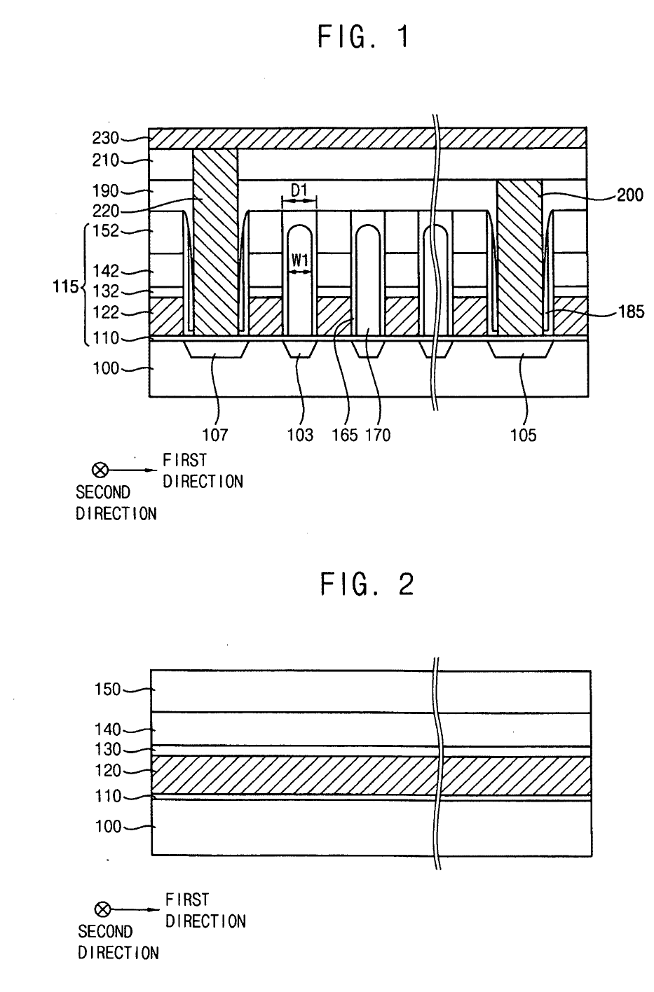

FIGS. 2 to 8 are cross-sectional views illustrating a method of manufacturing a semiconductor device in accordance with an example embodiment.

Referring to FIG. 2, a tunnel insulation layer 110, a floating gate layer 120, a blocking layer 130, a control gate layer 140, and a gate mask layer 150 may be sequentially formed on a substrate 100.

The substrate 100 may include a semiconductor substrate, e.g., a silicon substrate, germanium substrate or a silicon-germanium substrate, and a silicon-on-insulator (SOI) substrate or a germanium-on-insulator (GOI) substrate. The substrate 100 may further include a plurality of wells including p-type impurities or n-type impurities.

The tunnel insulation layer 110 may be formed using a low-k dielectric material, e.g., silicon oxide, silicon oxy nitride, and doped silicon oxide. The floating gate layer 120 may be formed using highly doped polysilicon or metal having a relatively high work function (e.g., tungsten, titanium, cobalt, and nickel).

The blocking layer 130 may include a high-k dielectric material, e.g., hafnium oxide, titanium oxide, tantalum oxide, zirconium oxide, aluminum oxide, lanthanum oxide, and strontium titanium oxide. Alternatively, the blocking layer 130 may have an ONO layer structure including oxide material and nitride material.

The control gate layer 140 may be formed using doped polysilicon, metal or metal nitride, e.g., titanium nitride and tantalum nitride. According to some example embodiments, the control gate layer 140 may include a polysilicon layer, an ohmic layer, a diffusion stop layer, an amorphous layer and a metal layer, which may be stacked sequentially. The ohmic layer may include, e.g., titanium, tantalum, tungsten, molybdenum, or alloys thereof, and the diffusion stop layer may include, e.g., tungsten nitride, titanium nitride, tantalum nitride, or molybdenum nitride. The amorphous layer may include, for example, metal silicide (e.g., amorphous tungsten silicide, amorphous titanium silicide, amorphous molybdenum silicide, and amorphous tantalum silicide), and the metal layer may include, e.g., tungsten, titanium, tantalum, molybdenum or alloys thereof.

Further, the gate mask layer 150 may be formed, e.g., using silicon nitride.

In other example embodiments, a charge trapping layer may be formed instead of the floating gate layer 120. The charge trapping layer may include, e.g., silicon nitride, silicon oxy nitride, hafnium silicon oxide, or aluminum oxide so that the charge trapping layer may trap or store a charge.

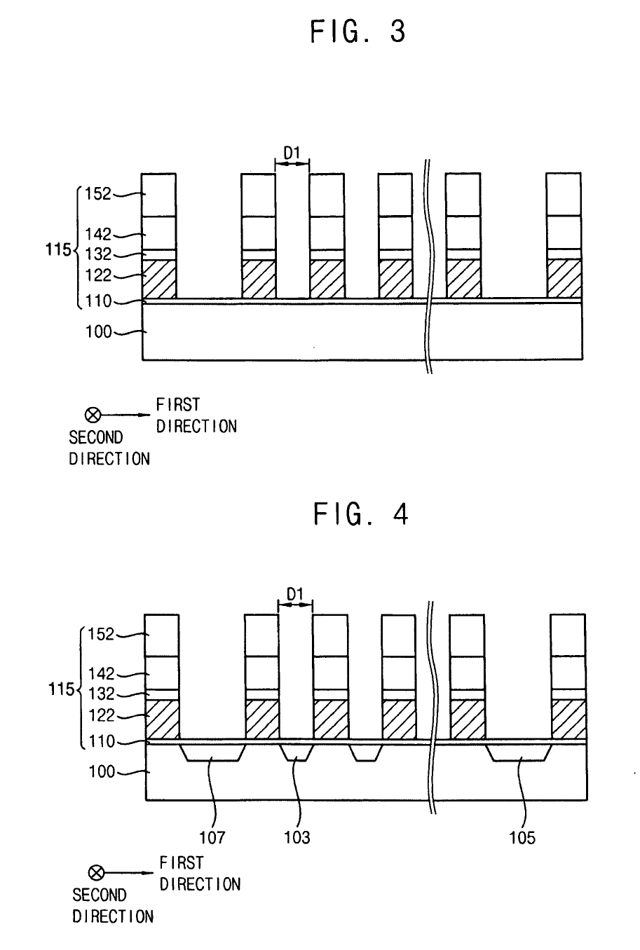

Referring to FIG. 3, the gate mask layer 150, the control gate layer 140, the blocking layer 130, and the floating gate layer 120 may be partially removed to form a plurality of gate structures 115 including the tunnel insulation layer 110, a floating gate 122, a blocking pattern 132, a control gate 142, and a gate mask 152.

The floating gate 122, the blocking pattern 132, the control gate 142, and the gate mask 152 may be sequentially stacked on the tunnel insulation layer 110. The plurality of gate structures 115 may be arranged in the first direction. Each of the gate structures 115 may extend in a second direction substantially perpendicular to the first direction.

A first distance D1 may be defined as a shortest distance between the adjacent gate structures 115 in the first direction. For example, the first distance D1 may be about 5 nm to about 20 nm.

Referring to FIG. 4, impurities may be implanted into the substrate 100 using the gate structures 115 as an ion implantation mask, thereby forming impurity regions 103, 105 and 107 at upper portions of the substrate 100.

The first impurity region 103 may be disposed between the adjacent gate structures 115 spaced apart from each other at the first distance D1, and the second and third impurity regions 105 and 107 may be disposed between the gate structures 115 spaced apart from each other at a distance substantially larger than the first distance D1.

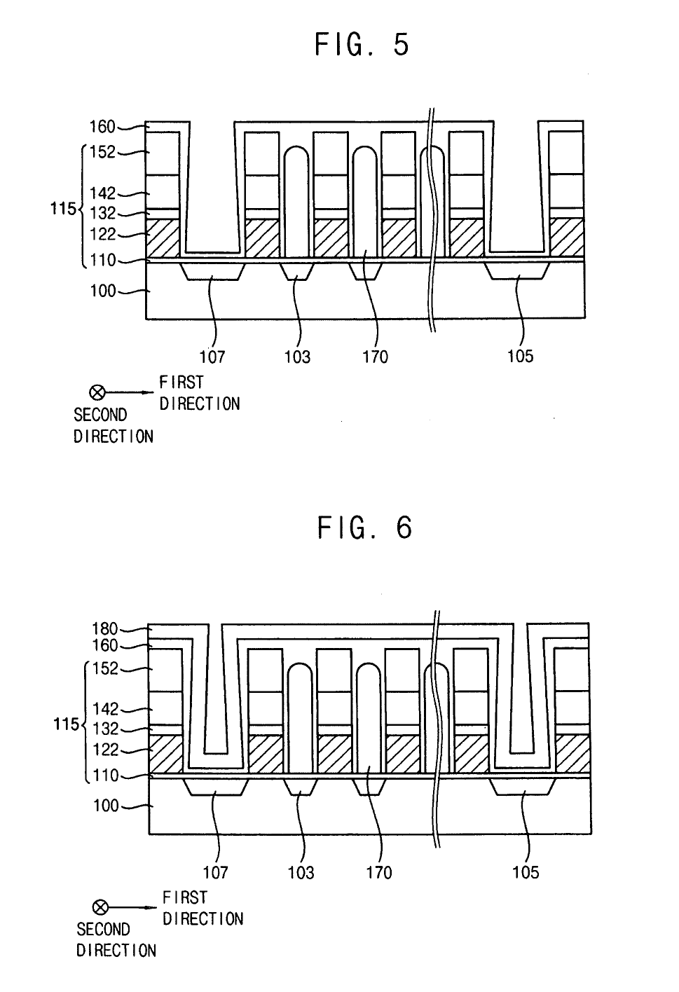

Referring to FIG. 5, an insulation layer 160 covering the gate structures 115 may be formed on the substrate 100 by performing, for example, a chemical vapor deposition process.

The insulation layer 160 may be formed, for example, using silicon oxide having relatively poor step coverage such that an air gap 170 may be formed in the insulation layer 160. For example, the insulation layer 160 may be formed by a chemical vapor deposition (CVD) process, a plasma enhanced CVD (PECVD) process, or a low pressure CVD (LPCVD) process.

A process condition, e.g., a temperature in a process chamber and a pressure of a source gas, may be adjusted to decrease the step coverage. Accordingly, the air gap 170 having a relatively large width may be formed in the insulation layer 160 between the adjacent gate structures 115. In example embodiments, a plurality of air gaps 170 may be arranged in the first direction, and each of the air gaps 170 may extend in the second direction.

In one example embodiment, the insulation layer 160 may be formed by the PECVD process using SiH₄ gas as a source gas and N₂O gas as an oxidation gas. Plasma may be generated in the process chamber during the PECVD process. For example, the PECVD process may be performed at a pressure of about 0.5 Torr to about 5 Torr and at a temperature of about 250° C. to about 350° C. When N₂O gas is used as the oxidation gas and the pressure of the process chamber is relatively low, the insulation layer 160 may have a poor gap fill characteristic.

The insulation layer 160 may be disposed on sidewalls of the gate structures 115 and may have a relatively small thickness. Accordingly, a first width W1 of the air gap 170, which is defined as a distance between the adjacent gate structures 115 in the first direction, may be relatively large. For example, the first width W1 of the air gap 170 in the first direction may be about 65% to about 70 of the first distance D1 between the adjacent gate structures 115. As the first width W1 increases, a coupling capacitance between the adjacent gate structures 115 may decrease.

The insulation layer 160 may be disposed above the tunnel insulation layer 110. That is, a top portion and side portions of the air gap 170 may be surrounded by the insulation layer 160, and a bottom portion of the air gap 170 may be surrounded by the tunnel insulation layer 110.

Referring to FIG. 6, a spacer layer 180 may be formed to cover the gate structures 115 and the insulation layer 160. For example, the spacer layer 180 may be formed using silicon nitride.

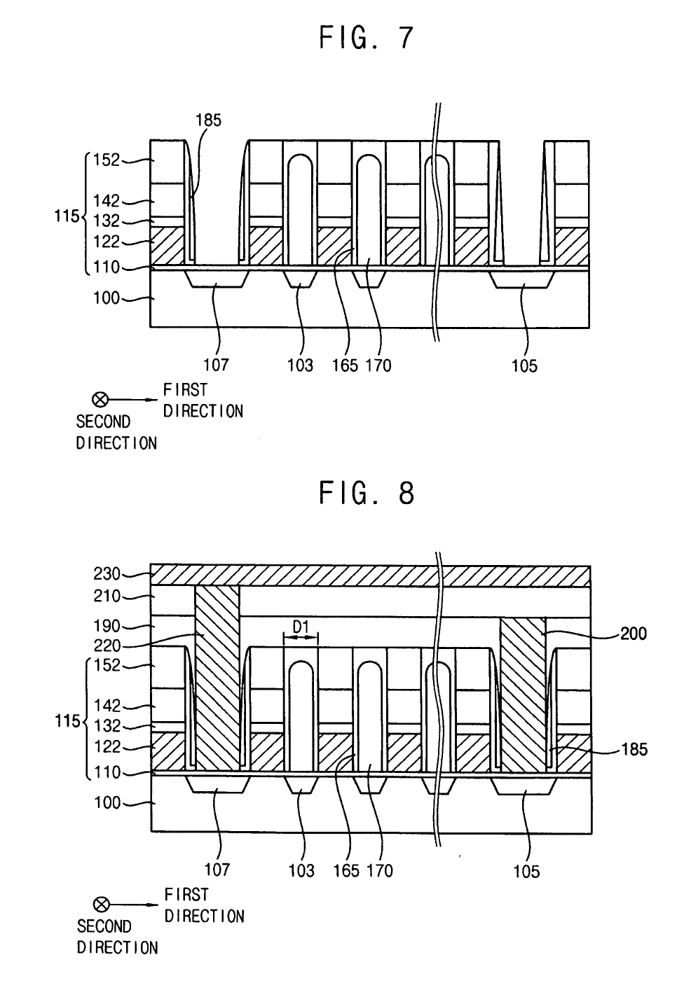

Referring to FIG. 7, a chemical mechanical polishing (CMP) process and/or an etch back process may be performed to remove upper portions of the spacer layer 180 and the insulation layer 160 on the gate structures 115, and then an etching process may be performed to remove lower portions of the spacer layer 180 and the insulation layer 160 on the second and third impurity regions 105 and 107.

Accordingly, an insulation layer patterns 165 may be formed between the adjacent gate structures 115 spaced apart from each other at the first distance D1, and a spacer 185 may be formed on a sidewall of the gate structure 115 spaced apart from each other at a distance substantially larger than the first distance D1.

Referring to FIG. 8, a first insulating interlayer 190 and a second insulating interlayer 210 may be formed to cover the gate structures 115, a common source line contact 200 and a bit line contact 220 may be formed, and then a bit line 230 may be formed on the second insulating interlayer 210.

The first insulating interlayer 190 may be formed to cover the gate structure 115, the insulation layer pattern 165, and the spacer 185. The first insulating interlayer 190 may be formed using an oxide, e.g., boron-doped phosphosilicate glass (BPSG), undoped silica glass (USG), spin-on glass (SOG) and/or HDP-CVD oxide.

The common source line contact 200 may be formed through the first insulating interlayer 190 such that the common source line contact 200 may directly contact the second impurity region 105. For example, the common source line contact 200 may be formed using doped polysilicon, metal, or metal silicide.

The second insulating interlayer 210 may be formed on the first insulating interlayer 190 and the common source line contact 200. The second insulating interlayer 210 may be formed using a material substantially the same as that of the first insulating interlayer 190.

The bit line contact 220 may be formed through the first and second insulating interlayers 190 and 210 such that the bit line contact 220 may directly contact the third impurity region 107. The bit line contact 220 may be formed using doped polysilicon, metal or metal silicide.

The bit line 230 electrically connected to the bit line contact 220 may be formed on the second insulating interlayer 210. The bit line 230 may extend in the first direction, and may include doped polysilicon, metal or metal silicide.

According to example embodiments, the insulation layer 160 may be formed by the PECVD process using SiH₄ gas as a source gas and N₂O gas as an oxidation gas at a relative low pressure. The insulation layer 160 formed by the PECVD process may have a relatively poor gap fill characteristic so that the air gap 170 having a relatively large width may be formed in the insulation layer 160. Accordingly, a parasitic capacitance between the adjacent gate structures 115 may decrease.

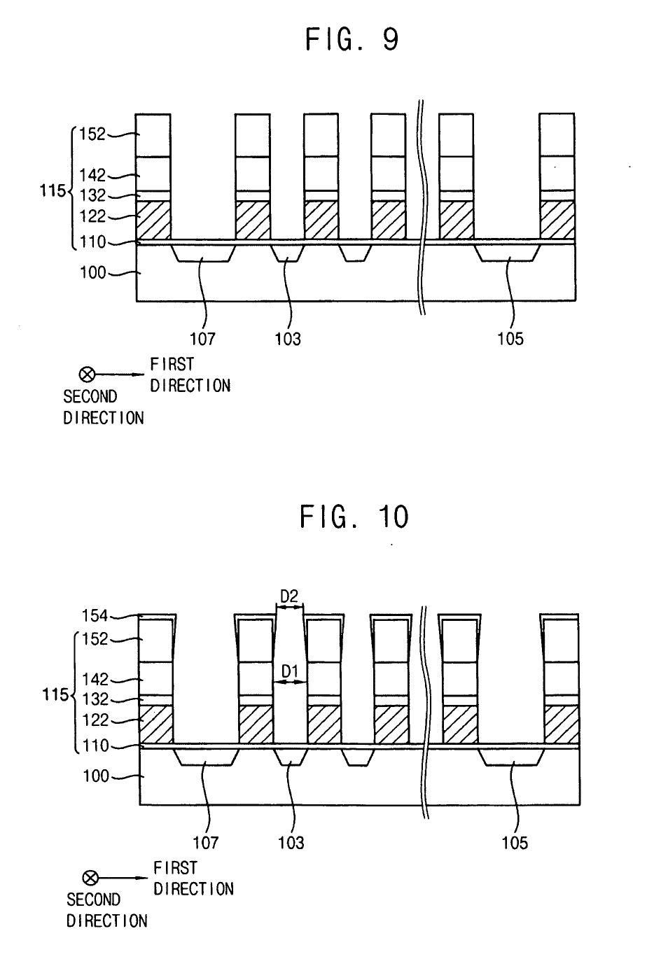

FIGS. 9 to 12 are cross-sectional views illustrating a method of manufacturing a semiconductor device in accordance with a example embodiment. The method illustrated in FIGS. 9 to 12 may be substantially the same as or similar to those illustrated with reference to FIGS. 2 to 8 except for a plasma process. Thus, like reference numerals refer to like elements, and repetitive explanations thereon may be omitted herein.

Referring to FIG. 9, processes substantially the same as or similar to those illustrated with reference to FIGS. 2 and 3 may be performed.

For example, a tunnel insulation layer 110, a floating gate layer, a blocking layer, a control gate layer, and a gate mask layer may be sequentially formed on a substrate 100, and then the floating gate layer, the blocking layer, the control gate layer and the gate mask layer may be partially removed to form a plurality of gate structures 115 including a floating gate 122, a blocking pattern 132, a control gate 142, and a gate mask 152. Further, impurity regions 103, 105, and 107 may be formed at upper portions of substrate 100 adjacent to the gate structures 115.

The floating gate 122 and the control gate 142 may include a material having a relatively high resistance to an oxidation. Further, the gate mask 152 may include silicon nitride.

Referring to FIG. 10, a plasma process may be performed to partially oxidize the gate mask 152 such that an oxidation pattern 154 may be formed on a top surface and a sidewall of the gate mask 152.

In example embodiments, the plasma process may be performed using an oxidation gas and an inert gas. For example, the oxidation gas may include, e.g., oxygen gas (O₂), nitrogen monooxide gas (NO), nitrous oxide gas (N₂O), ozone gas (O₃), or water gas (H₂O).

The plasma process may partially oxidize the gate mask 152, and the oxidized portion may be referred to as the oxidation pattern 154. When the gate mask 152 includes silicon nitride, the oxidation pattern 154 may include silicon oxide or silicon oxynitride. During the plasma process, a volume of the oxidation pattern 154 may increase, and thus the oxidation pattern 154 may protrude in a direction substantially parallel to a top surface of the substrate 100. Thus, a second distance D2 between the adjacent oxidation patterns 154 in the first direction may be smaller than a first distance D1 between the adjacent gate structures 115. Accordingly, the oxidation patterns 154 having an overhang shape may be formed on the gate mask 152.

A process condition of the plasma process may be adjusted such that the elements under the gate mask 152 (e.g., the floating gate 122 and the control gate 142) may not be affected by the plasma process.

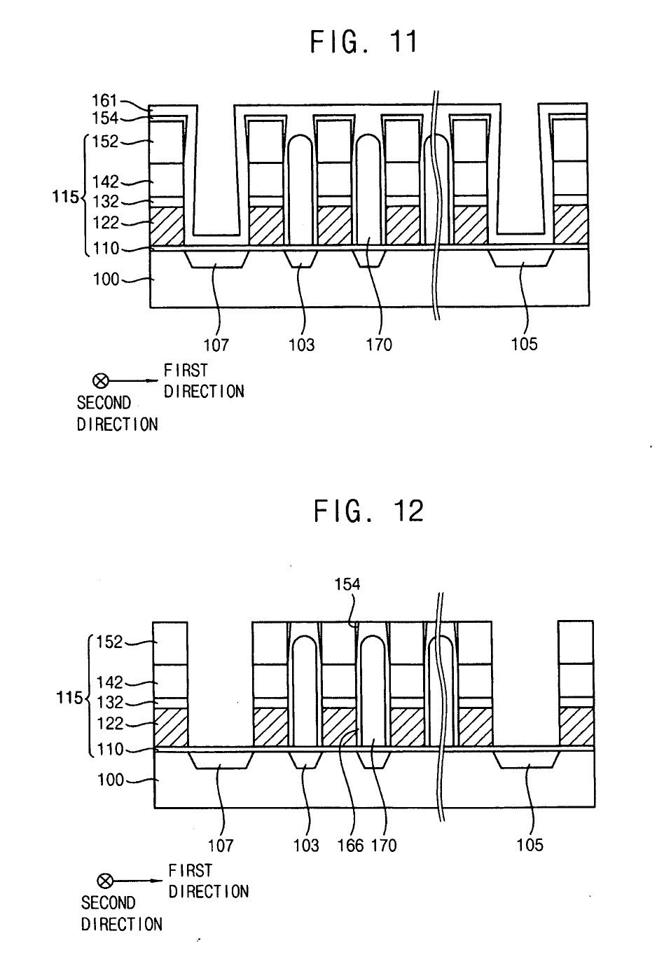

Referring to FIG. 11, an insulation layer 161 covering the gate structures 115 may be formed on the substrate 100 by performing a chemical vapor deposition process.

The process for forming the insulation layer 161 may be substantially the same as or similar to the process for forming the insulation layer 160 described with reference to FIG. 5. Because the oxidation pattern 154 may be formed on the sidewall of the gate mask 152, the insulation layer 161 may not fill a space between the gate structures 115. Further, a width of an air gap 170 may increase depending on the overhang of the oxidation pattern 154 on the gate mask 152.

Referring to FIG. 12, a chemical mechanical polishing (CMP) process and/or an etch back process may be performed to remove upper portions of the oxidized pattern 154 and the insulation layer 161 on the gate structures 115 such that an insulation layer patterns 166 may be formed between the gate structures 115.

Then, processes illustrated with reference to FIGS. 7 and 8 may be performed to form the semiconductor device.

According to this example embodiment, the gate mask 152 may be oxidized to form the oxidation pattern 154, and the insulation layer 161 may be formed by the PECVD process using SiH₄ gas and N₂O gas. Thus, the air gap 170 may be formed to have a relatively large width. Accordingly, a coupling capacitance between the adjacent gate structures 115 may decrease.

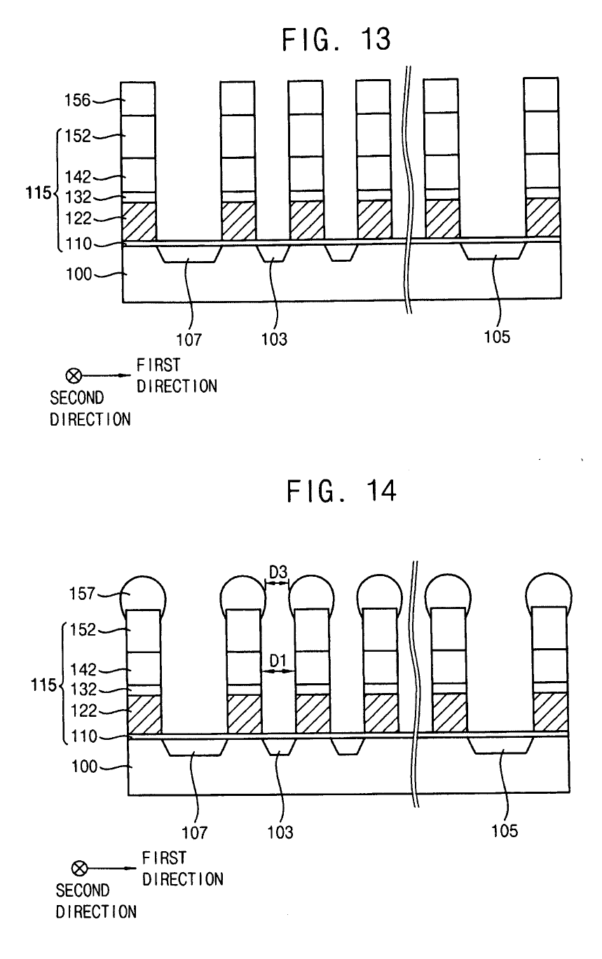

FIGS. 13 to 16 are cross-sectional views illustrating a method of manufacturing a semiconductor device in accordance with an example embodiment. The method illustrated in FIGS. 13 to 16 may be substantially the same as or similar to those illustrated with reference to FIGS. 2 to 8 except for a sputtering process. Thus, like reference numerals refer to like elements, and repetitive explanations thereon may be omitted herein.

Referring to FIG. 13, processes substantially the same as or similar to those illustrated with reference to FIGS. 2 and 3 may be performed. In this embodiment, a target pattern 156 may be formed on the gate mask 152.

For example, a tunnel insulation layer 110, a floating gate layer, a blocking layer, a control gate layer, a gate mask layer, and a target layer may be sequentially formed on a substrate 100. Then, the floating gate layer, the blocking layer, the control gate layer, the gate mask layer, and the target layer may be partially removed to form a target pattern 156 and a plurality of gate structures 115 including a floating gate 122, a blocking pattern 132, a control gate 142, and a gate mask 152. For example, the target pattern 156 may include an oxide, e.g., silicon oxide or high density plasma (HDP) oxide.

Referring to FIG. 14, a sputtering process may be performed around the target pattern 156.

For example, plasma may be generated in a process chamber using an inert gas, e.g., an argon gas, or a helium gas, and the plasma may be applied to upper portion of the target pattern 156. The plasma may partially remove the silicon oxide from upper edges of the target pattern 156. In other example embodiments, other gases, e.g., a nitrogen gas or a hydrogen gas, may also be used to generate the plasma.

By the sputtering process, the target pattern 156 may be deformed into a dummy pattern 157 having an overhang shape. Therefore, a third distance D3 between the adjacent dummy patterns 157 may be smaller than a first distance D1 between the adjacent gate structures 115.

Referring to FIG. 15, an insulation layer 162 covering the gate structures 115 and the dummy patterns 157 may be formed on the substrate 100 by performing a chemical vapor deposition process.

The process for forming the insulation layer 162 may be substantially the same as or similar to the process for forming the insulation layer 160 described with reference to FIG. 5. Because the dummy pattern 157 may have the overhang shape, the insulation layer 162 may not fill a space between the gate structures 115. Further, a width of an air gap 170 may increase depending on the overhang shape of the dummy pattern 157.

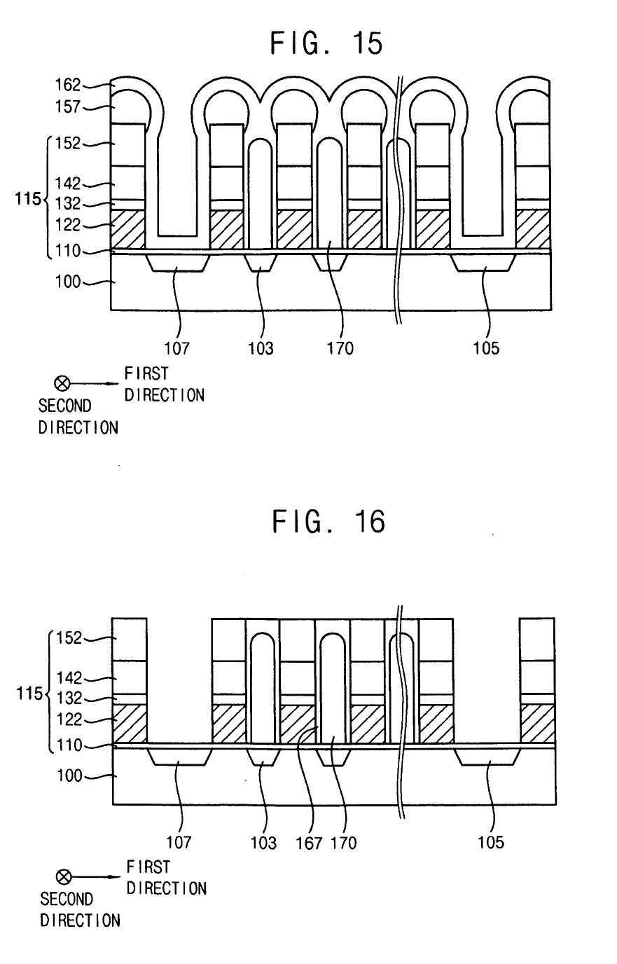

Referring to FIG. 16, a chemical mechanical polishing (CMP) process and/or an etch back process may be performed to remove an upper portion of the insulation layer 162 and the dummy pattern 157 on the gate structures 115 such that an insulation layer patterns 167 may be formed between the gate structures 115.

Then, processes illustrated with reference to FIGS. 7 and 8 may be performed to form the semiconductor device.

According to this example embodiment, the dummy pattern 157 may have the overhang shape, and the insulation layer 162 may be formed by the PECVD process using SiH₄ gas and N₂O gas. Thus, the air gap 170 having a relatively large width may be formed. Accordingly, a parasitic capacitance between the adjacent gate structures 115 may decrease.

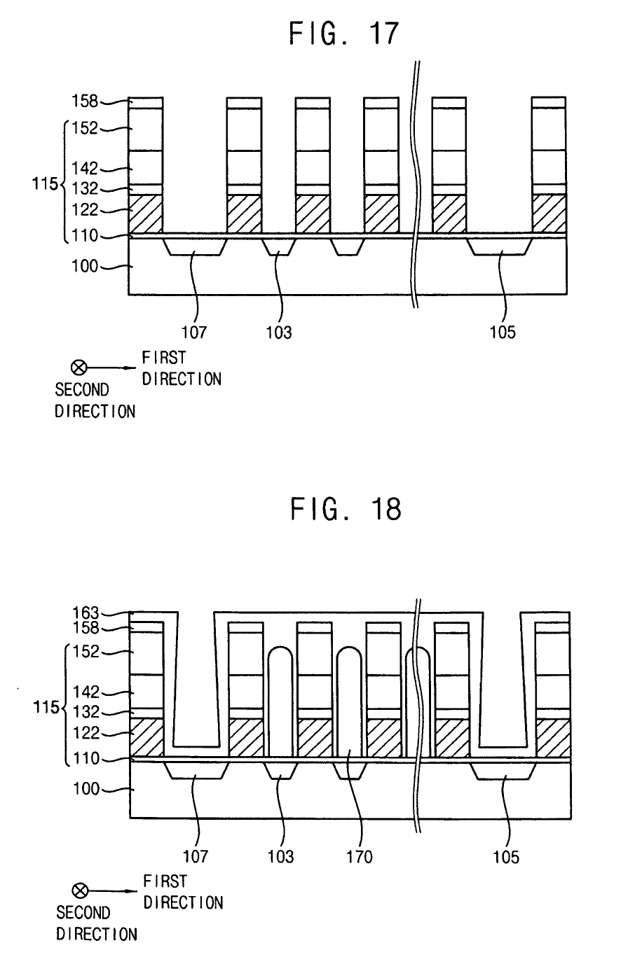

FIGS. 17 to 19 are cross-sectional views illustrating a method of manufacturing a semiconductor device in accordance with an example embodiment. The method illustrated in FIGS. 17 to 19 may be substantially the same as or similar to those illustrated with reference to FIGS. 2 to 8 except for a catalyst pattern 158. Thus, like reference numerals refer to like elements, and repetitive explanations thereon may be omitted herein.

Referring to FIG. 17, processes substantially the same as or similar to those illustrated with reference to FIGS. 2 and 3 may be performed. Further, the catalyst pattern 158 may be formed on the gate mask 152.

For example, a tunnel insulation layer 110, a floating gate layer, a blocking layer, a control gate layer, a gate mask layer and a catalyst layer may be sequentially formed on a substrate 100. Then the floating gate layer, the blocking layer, the control gate layer, the gate mask layer, and the catalyst layer may be partially removed to form the catalyst pattern 158 and a plurality of gate structures 115 including a floating gate 122, a blocking pattern 132, a control gate 142, and a gate mask 152.

For example, the catalyst pattern 158 may be formed using metal oxide. For example, the catalyst pattern 158 may include a zirconium oxide (e.g., ZrO₂, PbZrO₂, and BaZrO₃), a hafnium oxide (e.g., HfOx, HfON, and HfAlO), a lantanium oxide (e.g., LaO₃), an aluminium oxide (e.g., Al₂O₃ and AlZrO), a tantalium oxide (e.g., Ta₂O₅), titanium oxide (e.g., TiOx), or an yttrium oxide (e.g., Y₂O₃).

Referring to FIG. 18, an insulation layer 163 covering the gate structures 115 and the catalyst pattern 158 may be formed on the substrate 100 by performing a chemical vapor deposition process.

The process for forming the insulation layer 163 may be substantially the same as or similar to the process for forming the insulation layer 160 described with reference to FIG. 5. During the CVD process, an oxygen molecule may be dissociatively adsorbed adjacent to the catalyst pattern 158, and the oxygen molecule may be activated. Accordingly, the activated oxygen molecule may promote a chemical reaction (e.g., an oxidation of SiH₄) of the CVD process in the vicinity of the catalyst pattern 158. Accordingly, the insulation layer 163 may be deposited relatively fast around the catalyst pattern 158.

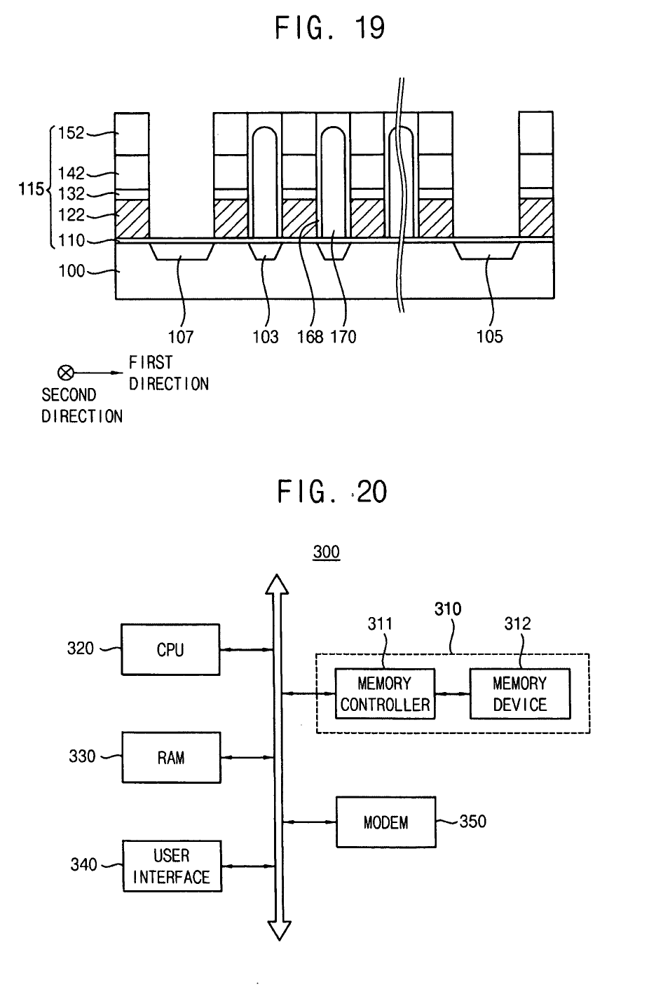

Referring to FIG. 19, a chemical mechanical polishing (CMP) process and/or an etch back process may be performed to remove upper portion of the insulation layer 163 and the catalyst pattern 158 on the gate structures 115 such that an insulation layer patterns 168 may be formed between the gate structures 115.

Then, processes illustrated with reference to FIGS. 7 and 8 may be performed to form the semiconductor device.

According to this example embodiment, the PECVD process using, e.g., SiH₄ gas and N₂O gas may be promoted by the catalyst pattern 158. Thus, an air gap 170 having a relatively large width may be formed. Accordingly, a parasitic capacitance between the adjacent gate structures 115 may decrease.

FIG. 20 is a block diagram illustrating a system including the semiconductor device in accordance with an example embodiment.

Referring to FIG. 20, a computing system 300 may include a microprocessor (CPU) 320 electrically connected to a system bus, a RAM 330, a user interface 340, a modem 350 (e.g., a baseband chipset), and a memory system 310. The memory system 310 may include a memory device 312 and a memory controller 311. The memory controller 311 may be configured to control the memory device 312. The memory system 310 may be, for example, a memory card or a solid state disk (SSD). When the computing system 300 is used in a mobile device, a battery may be further provided to supply an operating voltage to the computing system 300. In some example embodiments, the computing system 300 may include an application chipset, a camera image processor, a mobile DRAM, etc.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the present inventive concepts. Accordingly, all such modifications are intended to be included within the scope of the present inventive concepts as defined in the claims. In the claims, means-plus-function clauses are intended to cover the structures described herein as performing the recited function and not only structural equivalents but also equivalent structures.

What is claimed is:

1. A method of forming a semiconductor device, comprising:
forming a plurality of gate structures on a substrate, the gate structures spaced apart from each other in a first direction; and
forming an insulation layer pattern by performing a chemical vapor deposition process using SiH₄ gas as a source gas, the insulation layer pattern partially defining an air gap between the adjacent gate structures,
wherein a width of the air gap in the first direction is about 65% to about 70% of a distance between the adjacent gate structures.

2. The method of claim 1, wherein the insulation layer pattern defines a top portion and side portions of the air gap.

3. The method of claim 1, wherein the forming an insulation layer pattern forms the insulation layer pattern using silicon oxide.

4. The method of claim 1, wherein the performing a chemical vapor deposition process includes generating plasma in a process chamber.

5. The method of claim 1, wherein the performing a chemical vapor deposition process includes using N₂O gas as an oxidation gas.

6. The method of claim 1, wherein the forming a plurality of gate structures comprises:
sequentially forming a tunnel insulation layer, a floating gate layer, a blocking layer, a control gate layer, and a gate mask layer on the substrate; and
partially removing the floating gate layer, the blocking layer, the control gate layer, and the gate mask layer to form a floating gate, a blocking pattern, a control gate, and a gate mask, respectively.

7. The method of claim 6, further comprising:
partially oxidizing the gate mask to form an oxidation pattern before performing the chemical vapor deposition process, the oxidation pattern projecting in a direction parallel to a top surface of the substrate,
wherein the forming a gate mask layer forms the gate mask layer using silicon nitride.

8. The method of claim 6, further comprising:
forming a plurality of target patterns on respective ones of the gate structures; and
performing a sputtering process using the target patterns as a sputtering target before the forming an insulation layer pattern such that a distance between the adjacent target patterns is reduced.

9. The method of claim 6, further comprising:
forming a plurality of catalyst patterns on respective ones of the gate structures,
wherein the catalyst patterns promote an oxidation of the source gas.

10. The method of claim 6, wherein the tunnel insulation layer defines a bottom portion of the air gap.

11. The method of claim 1, wherein the distance between the adjacent gate structures is about 5 nm to about 20 nm.

12. A semiconductor device, comprising:
a plurality of gate structures on a substrate, the gate structures spaced apart from each other in a first direction; and
an insulation layer pattern between the adjacent gate structures, the insulation layer pattern partially defining an air gap extending in a second direction, the second direction substantially perpendicular to the first direction,
wherein a width of the air gap in the first direction is about 65% to about 70% of a distance between the adjacent gate structures.

13. The semiconductor device of claim 12, wherein each of the gate structures includes a stack of a tunnel insulation layer, a floating gate, a blocking pattern, a control gate, and a gate mask sequentially stacked on the substrate.

14. The semiconductor device of claim 12, wherein the insulation layer pattern defines a top portion and side portions of the air gap, and the tunnel insulation layer defines a bottom surface of the air gap.

15. The semiconductor device of claim 12, wherein the insulation layer pattern includes silicon oxide.

16. A method of forming a semiconductor device, comprising:
forming a plurality of gate structures on a substrate, the gate structures spaced apart from each other in a first direction;
forming a plurality of intermediate structures on top portions of respective ones of the gate structures such that the intermediate structures at least partially cover sidewalls of respective ones of the gate structures; and
forming an insulation layer on the intermediate structures, the insulation layer filling openings defined between adjacent intermediate structures and covering side portions of the gate structures such that a plurality of air gaps are arranged under the insulation layer, the air gaps extending in a second direction, the second direction perpendicular to the first direction.

17. The method of claim 16, wherein the forming a plurality of gate structures comprises:
sequentially forming a tunnel insulation layer, a floating gate layer, a blocking layer, a control gate layer, and a gate mask layer on the substrate; and
partially removing the floating gate layer, the blocking layer, the control gate layer, and the gate mask layer to form the gate structures each including a floating gate, a blocking pattern, a control gate, and a gate mask.

18. The method of claim 17, wherein the forming a plurality of intermediate structures includes partially oxidizing the gate mask.

19. The method of claim 17, wherein
the forming a plurality of gate structures further includes forming a plurality of target patterns on respective ones of the gate mask patterns; and
the forming a plurality of intermediate structures includes performing a sputtering process around the target patterns.

20. The method of claim 17, wherein
the forming a plurality of gate structures further includes forming a plurality of catalyst patterns on respective ones of gate mask patterns.
